(19) United States
(12) Patent Application Publication
(10) Pub. No.: US 2024/0155927 A1
(43) Pub. Date: May 9, 2024

(54) DISPLAY DEVICE INCLUDING A WINDOW PROTECTION LAYER

(71) Applicant: SAMSUNG DISPLAY CO., LTD., YONGIN-SI (KR)

(72) Inventors: SEUNGHWAN CHUNG, Yongin-si (KR); HUNG KUN AHN, Yongin-si (KR); MINSU KIM, Yongin-si (KR)

(21) Appl. No.: 18/500,487

(22) Filed: Nov. 2, 2023

(30) Foreign Application Priority Data
Nov. 4, 2022 (KR) 10-2022-0145875

(51) Int. Cl. H10K 59/80; H10K 59/126; H10K 59/38

(52) U.S. Cl. CPC H10K 59/8792; H10K 59/126; H10K 59/38; H10K 59/879; H10K 2102/351

(57) ABSTRACT

A display device includes a display panel, a window disposed on the display panel, and a window protection layer disposed on the window, wherein at least one of the display panel or the window protection layer selectively absorbs light in a yellow-green hue, a green-blue hue, or a blue-red hue.

This application claims priority under 35 USC § 119 to Korean Patent Application No. 10-2022-0145875, filed on Nov. 4, 2022, in the Korean Intellectual Property Office (KIPO), the disclosure of which is herein incorporated by reference in its entirety.

### TECHNICAL FIELD

Embodiments of the present inventive concept relate to a display device. More specifically, embodiments of the present inventive concept relate to a display device with improved reflective color.

### DISCUSSION OF RELATED ART

In a display device including wires and electrodes made of metal, external light incident on the display device may be reflected by the wires and electrodes. To prevent reflection of the external light, a display device generally includes a polarizer. While the polarizer may prevent reflection of the external light, light efficiency of the display device may be reduced due to the polarizer.

### SUMMARY

Embodiments provide a display device with improved reflective color and improved image quality.

Embodiments provide a method for manufacturing the display device.

A display device according to an embodiment may include a display panel, a window disposed on the display panel, and a window protection layer disposed on the window, wherein at least one of the display panel or the window protection layer selectively absorbs light in a yellow-green hue, a green-blue hue, or a blue-red hue.

In an embodiment, the display device may include a folding area of the display panel, the window, and the window protection layer, and a flat area adjacent to the folding area.

In an embodiment, at least one of the display panel or the window protection layer that selectively absorbs light in the yellow-green hue, the green-blue hue, or the blue-red hue, may transmit light having a different wavelength than the absorbed light.

In an embodiment, the display device may satisfy at least one of Equation 1 or Equation 2:

A1×A2<0 [Equation 1]

B1×B2<0 [Equation 2]
wherein A1 is a* value of the display panel on a red-green coordinate axis, A2 is a* value of the window protection layer on the red-green coordinate axis, B1 is b* value of the display panel on a yellow-blue coordinate axis, and B2 is b* value of the window protection layer on the yellow-blue coordinate axis.

In an embodiment, the window protection layer may include a protective film disposed on the window and an adhesive layer disposed between the window and the protective film.

In an embodiment, the window protection layer may further include a color adjustment layer disposed below the protective film, wherein the color adjustment layer may selectively absorb light in a specific wavelength range.

In an embodiment, the color adjustment layer may have a thickness of about 10 um or less.

In an embodiment, the protective film may selectively absorb light in a specific wavelength range and the adhesive layer may selectively absorbs light of a second specific wavelength range, wherein the first specific wavelength range and the second specific wavelength range are one of a same range or a different range.

In an embodiment, the window protection layer may further include a functional layer disposed on the protective film and having a thickness of about 10 um or less.

In an embodiment, the functional layer may include a hard coating layer disposed on the protective film.

In an embodiment, the hard coating layer may selectively absorb light in a specific wavelength range.

In an embodiment, the functional layer may include a first refractive layer disposed on the protective film and a second refractive layer disposed on the first refractive layer, having a refractive index lower than a refractive index of the first refractive layer, and may include an anti-fingerprint material.

In an embodiment, the first refractive layer may selectively absorb light of a specific wavelength range.

In an embodiment, the functional layer may include a first refractive layer disposed on the protective film, a second refractive layer disposed on the first refractive layer and having a refractive index lower than a refractive index of the first refractive layer, and an anti-fingerprint layer disposed on the second refractive layer.

In an embodiment, the display panel may include a substrate, a light emitting devices disposed on the substrate, and an anti-reflection layer disposed on the light emitting devices and including a light blocking member.

In an embodiment, the anti-reflection layer may further include a plurality of color filters, wherein the color filters correspond to the light emitting devices, and an overcoat layer disposed on the anti-reflection layer.

A display device according to an embodiment may include a display panel, a window disposed on the display panel, and a window protection layer disposed on the window, wherein each of the display panel, the window, and the window protection layer include a folding area and a flat area adjacent to the folding area, and a saturation of a reflective color exhibited by the display panel is greater than a saturation of a color displayed by the display device.

In an embodiment, the display device may satisfy at least one of Equation 3 or Equation 4:

|A1|>|A3| [Equation 3]

|B1|>|B3| [Equation 4]
wherein A1 is a* value of the display panel on a red-green coordinate axis, A3 is a* value of the display device on the red-green coordinate axis, B1 is b* value of the display panel on a yellow-blue coordinate axis, and B2 is b* value of the display device on the yellow-blue coordinate axis.

In an embodiment, the display device may satisfy at least one of Equation 1 or Equation 2:

A1×A2<0 [Equation 1]

B1×B2<0 [Equation 2]

wherein A1 is a* value of the display panel on a red-green coordinate axis, A2 is a* value of the window protection layer on the red-green coordinate axis, B1 is b* value of the display panel on a yellow-blue coordinate axis, and B2 is b* value of the window protection layer on the yellow-blue coordinate axis.

In an embodiment, a display device without a polarizer may include a display panel, a window disposed on the display panel, and a window protection layer disposed on the window, wherein each of the display panel, the window, and the window protection layer include a folding area and a flat area adjacent to the folding area, wherein the window protection layer offsets a reflective color of the display panel for a specific range of wavelengths, and wherein a saturation of a color displayed by the display device is less than a saturation of the reflective color exhibited by the display panel in the specific range of wavelengths.

In an embodiment, the window protection layer may have a structure in which a plurality of layers are stacked, and at least one of the plurality of layers may selectively absorb light in a specific wavelength range.

The display device according to embodiments may include the display panel, the window disposed on the display panel, and the window protection layer WPL which protects the window. The window protection layer may have a structure in which a plurality of layers including the protective film are stacked, and at least one of the plurality of layers of the window protection layer selectively absorbs light of a specific wavelength range. Accordingly, the window protection layer may adjust the reflective color of the display device. For example, a* value and b* value of the window protection layer in the CIE-Lab color coordinate system may be adjusted in response to a* value and the b* value of the display panel PNL in the CIE-Lab color coordinate system.

Accordingly, the reflective color of the display device may be adjusted by adjusting a* value and/or b* value of the window protection layer in the CIE-Lab color coordinate system without changing a structure and/or configuration of the display panel. Accordingly, the reflective color of the display device may be improved, and the image quality of the display device may be improved. In addition, the manufacturing process of the display device can be simplified, and the manufacturing cost of the display device can be reduced.

It is to be understood that both the foregoing general description and the following detailed description are exemplary and explanatory and are intended to provide further explanation of the invention as claimed.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to one or more embodiments.

FIG. 2 is a cross-sectional view illustrating the display device of FIG. 1 according to an embodiment.

FIG. 3 is a cross-sectional view illustrating a display panel included in the display device of FIG. 2.

FIG. 4 is a diagram illustrating a CIE-Lab color coordinate system.

FIG. 5 is a cross-sectional view illustrating the display device of FIG. 1 according to an embodiment.

FIG. 6 is a cross-sectional view illustrating the display device of FIG. 1 according to an embodiment.

FIG. 7 is a cross-sectional view illustrating the display device of FIG. 1 according to an embodiment.

FIG. 8 is a cross-sectional view illustrating the display device of FIG. 1 according to an embodiment.

FIG. 9 is a cross-sectional view illustrating the display device of FIG. 1 according to an embodiment.

### DETAILED DESCRIPTION

Embodiments of the present inventive concept will now be described more fully hereinafter with reference to the accompanying drawings. The inventive concept may, however, be embodied in many different forms, and should not be construed as limited to embodiments set forth herein. Rather, embodiments are provided so that this disclosure will be thorough and complete, and will fully convey the scope of the inventive concept to those skilled in the art Like reference numerals refer to like elements throughout.

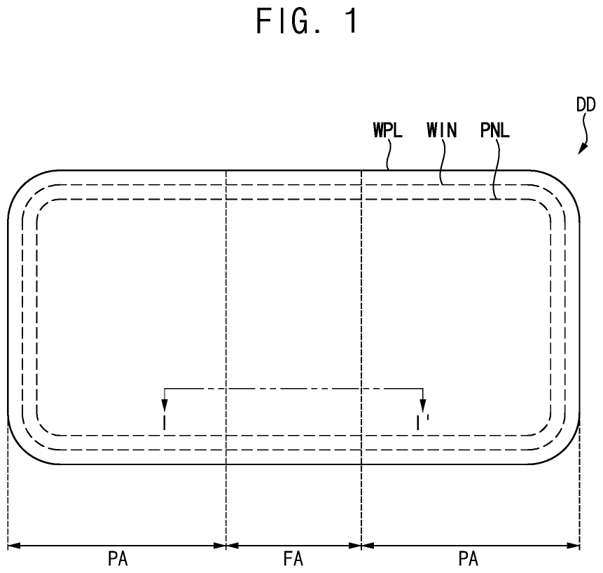

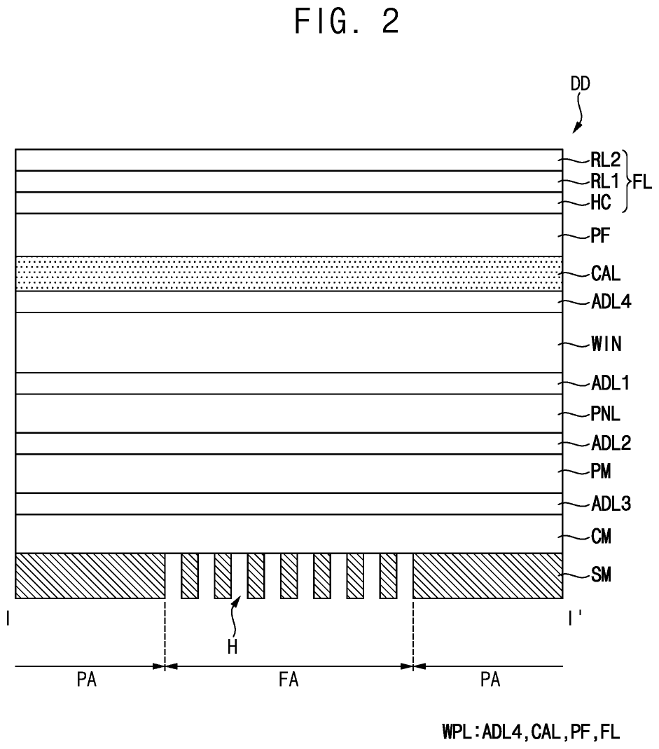

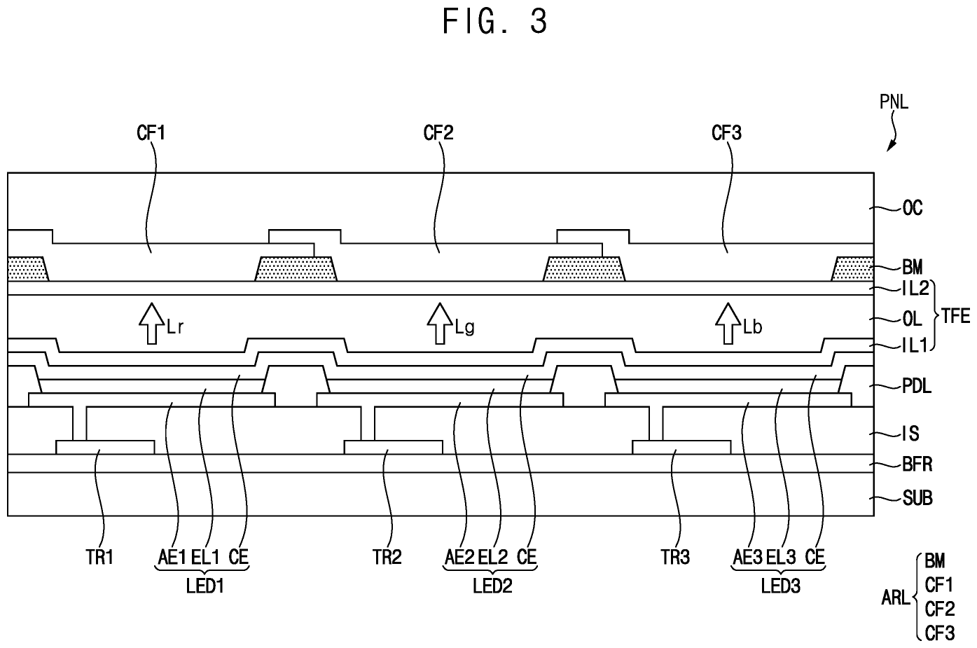

FIG. 1 is a plan view illustrating a display device according to some embodiments. FIG. 2 is a cross-sectional view illustrating the display device of FIG. 1 according to an embodiment. FIG. 3 is a cross-sectional view illustrating a display panel included in the display device of FIG. 2. For example, FIG. 2 may be a cross-sectional view taken along line I-I′ of FIG. 1 according to an embodiment.

Referring to FIG. 1, a display device DD according to some embodiments may include a display panel PNL, a window WIN, and a window protection layer WPL. The window WIN may be disposed on the display panel PNL. The window protection layer WPL may be disposed on the window WIN. For example, the window WIN may be disposed between the display panel PNL and the window protection layer WPL.

The display panel PNL of the display device DD may display an image. The window WIN may have one or more functions. For example, the window WIN may protect the display panel PNL. The window protection layer WPL may have one or more functions. For example, the window protection layer WPL may be disposed on the display device DD and may protect the window WIN.

In an embodiment, the display panel PNL may include a folding area FA and a flat area PA adjacent to the folding area FA. For example, as shown in FIG. 1, the display panel PNL may include the folding area FA overlapping a central portion of the display panel PNL and the flat area PA adjacent to left and right sides of the folding area FA. The display panel PNL may be folded in the folding area FA. Accordingly, the window WIN and the window protection layer WPL on the display panel PNL may be folded in the folding area FA.

Referring to FIG. 2 and FIG. 3, the display device DD according to an embodiment may include the display panel PNL, the window WIN, and the window protection layer WPL. The display device DD according to an embodiment may further include, for example, a protection member PM, and a cushion member CM, a support member SM, a first adhesive layer ADL1, a second adhesive layer ADL2, and a third adhesive layer ADL3.

The window protection layer WPL may include, for example, a fourth adhesive layer ADL4, a color adjustment layer CAL, a protective film PF, and a functional layer FL. The functional layer FL may include, for example, a hard coating layer HC, a first refractive layer RL1 and a second refractive layer RL2.

As shown in FIG. 3, the display panel PNL may include a substrate SUB, a buffer layer BFR, a first driving element TR1, a second driving element TR2, and a third driving element TR3. The display panel PNL may further include an insulating structure IS, a pixel defining layer PDL, a first light emitting device LED1, a second light emitting device LED2, and a third light emitting device LED3. The display panel PNL may further include an encapsulation layer TFE, an anti-reflection layer ARL, and an overcoat layer OC. The anti-reflection layer ARL may include a light blocking member BM, a first color filter CF1, a second color filter CF2, and a third color filter CF3.

The substrate SUB may include, for example, glass, quartz, or plastic. For example, the substrate SUB may be a plastic substrate and may include polyimide PI. In an embodiment, the substrate SUB may have a structure in which at least one polyimide layer and at least one barrier layer are alternately stacked.

The buffer layer BFR may be disposed on the substrate SUB. The buffer layer BFR may include silicon oxide, silicon nitride, or the like. The buffer layer BFR may prevent impurities from diffusing onto the substrate SUB. In other embodiments, the buffer layer BFR may be omitted.

The first to third driving elements TR1, TR2, and TR3 may be disposed on the buffer layer BFR. In an embodiment, each of the first to third driving elements TR1, TR2, and TR3 may include at least one thin film transistor. A channel layer of the transistor may include, for example, an oxide semiconductor, a silicon semiconductor, or an organic semiconductor. For example, the oxide semiconductor may include an oxide including at least one indium (In), gallium (Ga), tin (Sn), zirconium (Zr), vanadium (V), hafnium (Hf), cadmium (Cd), germanium (Ge), chromium (Cr), titanium (Ti), or zinc (Zn). The silicon semiconductor may include amorphous silicon, polycrystalline silicon, or the like.

The insulating structure IS may cover the first to third driving elements TR1, TR2, and TR3. The insulating structure IS may include a combination of an inorganic insulating layer and an organic insulating layer. For example, the inorganic insulating layer may include silicon oxide (SiOx), silicon nitride (SiNx), silicon carbide (SiCx), silicon oxynitride (SiOxNy), silicon oxycarbide (SiOxCy), or the like. In addition, the organic insulating layer may be formed of photoresist, polyacryl-based resin, polyimide-based resin, polyamide-based resin, siloxane-based resin, acrylic-based resin, epoxy-based resin, or the like. These materials may be used alone or in combination with each other.

First to third pixel electrodes AE1, AE2, and AE3 may be disposed on the insulating structure IS. Each of the first to third pixel electrodes AE1, AE2, and AE3 may include a conductive material such as a metal, an alloy, a conductive metal nitride, a conductive metal oxide, or a transparent conductive material. Each of the first to third pixel electrodes AE1, AE2, and AE3 may have a single-layer structure or a multi-layer structure including a plurality of conductive layers.

The first pixel electrode AE1 may be electrically connected to the first driving element TR1 through a contact hole formed in the insulating structure IS. The second pixel electrode AE2 may be electrically connected to the second driving element TR2 through a contact hole formed in the insulating structure IS. The third pixel electrode AE3 may be electrically connected to the third driving element TR3 through a contact hole formed in the insulating structure IS. The first to third pixel electrodes AE1, AE2, and AE3 may be electrically connected to the first to third driving elements TR1, TR2, and TR3 through respective contact holes formed in the insulating structure IS.

The pixel defining layer PDL may be disposed on the first to third pixel electrodes AE1, AE2, and AE3. The pixel defining layer PDL may include an organic insulating material. Examples of the organic insulating material that can be used as the pixel defining layer PDL may include photoresist, polyacryl-based resin, polyimide-based resin, polyamide-based resin, and siloxane-based resin, acrylic-based resin, epoxy-based resin, or the like. These materials may be used alone or in combination with each other. The pixel defining layer PDL may define a pixel opening exposing at least a portion of each of the first to third pixel electrodes AE1, AE2, and AE3. An emission area and a non-emission area of the display device DD may be defined by the pixel opening. For example, a portion where the pixel opening is located may correspond to the emission area, and a portion where the pixel defining layer PDL is disposed may correspond to the non-emission area.

First to third emission layers EL1, EL2, and EL3 may be disposed on the first to third pixel electrodes AE1, AE2, and AE3 exposed by the pixel opening of the pixel defining layer PDL. For example, the first emission layer EL1 may be disposed on the first pixel electrode AE1, the second emission layer EL2 may be disposed on the second pixel electrode AE2, and the third emission layer EL3 may be disposed on the third pixel electrode AE3. The first to third emission layers EL1, EL2, and EL3 may each be disposed in an emission area.

In an embodiment, the first emission layer EL1 may include a light emitting material emitting red light Lr, the second emission layer EL2 may include a light emitting material emitting green light Lg, and the third emission layer EL3 may include a light emitting material emitting blue light Lb. However, embodiments of the present invention are not necessarily limited thereto. For example, the emission layers may emit different wavelengths of light.

In an embodiment, a hole injection layer, a hole transport layer, an electron transport layer, an electron injection layer, or the like may be disposed above and/or below each of the first to third emission layers EL1, EL2, and EL3.

A common electrode CE may be disposed on the first to third emission layers EL1, EL2, and EL3. The common electrode CE may include a conductive material such as a metal, an alloy, a conductive metal nitride, a conductive metal oxide, or a transparent conductive material. The common electrode CE may have a single-layer structure or a multi-layer structure including a plurality of conductive layers. In an embodiment, the common electrode CE may continuously extend over a plurality of pixels.

The first light emitting device LED1 may include the first pixel electrode AE1, the first emission layer EL1, and the common electrode CE. The second light emitting device LED2 may include the second pixel electrode AE2, the second emission layer EL2, and the common electrode CE. The third light emitting device LED3 may include the third pixel electrode AE3, the third emission layer EL3, and the common electrode CE. In an embodiment, the first light emitting device LED1, the second light emitting device LED2, and the third light emitting device LED3 may be spaced apart from each other.

In an embodiment, the first light emitting device LED1 may emit red light Lr, the second light emitting device LED2 may emit green light Lg, and the third light emitting device LED3 may emit blue light Lb. However, embodiments of the present invention are not limited thereto. For example, the first to third light emitting devices LED1, LED2, and LED3 may emit different wavelengths or may emit a same wavelength.

Meanwhile, the light emitting devices included in the display device DD may not be limited to the first to third light emitting devices LED1, LED2, and LED3. For example, a light emitting device may also be a light emitting device that includes at least one of a micro-LED, a nano-LED, a quantum dot (QD), or a quantum rod (QR).

The encapsulation layer TFE may be disposed on the first to third light emitting devices LED1, LED2, and LED3. For example, the encapsulation layer TFE may be disposed on the common electrode CE. The encapsulation layer TFE may include at least one inorganic encapsulation layer and at least one organic encapsulation layer. In an embodiment, the encapsulation layer TFE may include a first inorganic encapsulation layer IL1 disposed on the common electrode CE, an organic encapsulation layer OL disposed on the first inorganic encapsulation layer IL1, and a second inorganic encapsulation layer IL2 disposed on the encapsulation layer OL.

The first color filter CF1 may correspond to the first light emitting device LED1. The second color filter CF2 may correspond to the second light emitting device LED2. The third color filter CF3 may correspond to the third light emitting device LED3. Each of the first to third color filters CF1, CF2, and CF3 may selectively transmit light of a specific wavelength range. For example, each of the first to third color filters CF1, CF2, and CF3 may selectively transmit light of different wavelength ranges.

In an embodiment, the first color filter CF1 may selectively transmit red light Lr, the second color filter CF2 may selectively transmit green light Lg, and the third color filter CF3 may selectively transmit blue light Lb. However, embodiments of the present invention are not necessarily limited thereto.

The light blocking member BM may be disposed at end portions of the first to third color filters CF1, CF2, and CF3. The light blocking member BM may be disposed between color filters CF1, CF2, and CF3. The end portions of the first to third color filters CF1, CF2, and CF3 may overlap the light blocking member BM. For example, the light blocking member BM entirely overlaps the non-emission area and may have a grid shape in a plan view.

In an embodiment, the light blocking member BM may absorb light from an exterior. Accordingly, the light blocking member BM may reduce a reflectance or prevent the reflection of the light from the exterior by the display device DD. Examples of materials that can be used as the light blocking member BM may include chromium (Cr), chromium oxide (CrOx), chromium nitride (CrNx), carbon black, a black pigment mixture, a black dye mixture, or the like. These materials may be used alone or in combination with each other.

The anti-reflection layer ARL may include the first color filter CF1, the second color filter CF2, the third color filter CF3, and the light blocking member BM. Accordingly, the display device DD may omit a polarizer. Accordingly, a structure of the display device DD can be simplified. Meanwhile, although not shown, in another embodiment, the first color filter CF1, the second color filter CF2, and the third color filter CF3 may be omitted.

The overcoat layer OC may be disposed on the anti-reflection layer ARL. The overcoat layer OC may include an organic material, an inorganic material, or a combination of an organic material and an inorganic material. Examples of materials that can be used as the overcoat layer OC may include polyimide, acryl, silicon oxide, or silicon nitride. These materials may be used alone or in combination with each other.

Referring to FIG. 2 again, the first adhesive layer ADL1 may be disposed on the display panel PNL. For example, the first adhesive layer ADL1 may be an optically transparent adhesive (OCA), an optically transparent adhesive resin (OCR), or a pressure-sensitive adhesive (PSA).

The window WIN may be disposed on the first adhesive layer ADL1. The window WIN may protect the display panel PNL. For example, the window WIN may be formed of transparent polyimide (colorless polyimide), ultra-thin tempered glass (UTG), polyethylene terephthalate (PET), polyimide (PI), polyethersulfone (PS), apolyacrylate (PAR), polyetherimide (PEI), polyethylene naphthalate (PEN), polyphenylene sulfide (PPS), polycarbonate (PC), or the like.

The second adhesive layer ADL2 may be disposed under the display panel PNL. For example, the second adhesive layer ADL2 may be an optically transparent adhesive (OCA), an optically transparent adhesive resin (OCR), or a pressure-sensitive adhesive (PSA).

The protective member PM may be disposed under the second adhesive layer ADL2. The protection member PM may have one or more functions. For example, the protection member PM may prevent penetration of moisture and oxygen from outside and may absorb external impact.

The third adhesive layer ADL3 may be disposed under the protection member PM. For example, the third adhesive layer ADL3 may be an optically transparent adhesive (OCA), an optically transparent adhesive resin (OCR), or a pressure-sensitive adhesive (PSA).

The cushion member CM may be disposed under the third adhesive layer ADL3. The cushion member CM may protect the display panel PNL. For example, the cushion member CM may buffer an external impact. For example, the cushion member CM may include a material capable of buffering an external impact. The cushion member CM may be a material containing air, such as a cushion or a sponge. In addition, the cushion member CM may include acrylic resin, polyurethane, thermoplastic polyurethane, latex, polyurethane foam, polystyrene foam, or the like.

The support member SM may be disposed under the cushion member CM. The support member SM may support the display panel PNL. For example, the support member SM may include invar, which is an alloy of nickel (Ni) and iron (Fe), stainless steel (SUS), titanium (Ti), copper (Cu), or the like. Also, holes H overlapping the folding area FA may be formed in the support member SM.

The fourth adhesive layer ADL4 may be disposed on the window WIN. For example, the fourth adhesive layer ADL4 may be formed of optically transparent adhesive (OCA), optically transparent adhesive resin (OCR), or pressure-sensitive adhesive (PSA).

The color adjustment layer CAL may be disposed on the fourth adhesive layer ADL4. In an embodiment, the color adjustment layer CAL may selectively absorb light of a specific wavelength range. Accordingly, the color adjustment layer CAL may adjust a reflective color of the display device DD. That is, a color gamut of the display device DD may be improved by the color adjustment layer CAL.

In an embodiment, the color adjustment layer CAL may selectively absorb light other than a wavelength range between about 450 nm and about 500 nm. In other words, the color adjustment layer CAL may selectively transmit light in a wavelength range between about 450 nm and about 500 nm. That is, the color adjustment layer CAL may selectively absorb light other than a blue light wavelength range. However, the range of wavelengths is not limited to the above example, and the range of wavelengths corresponding to the blue light may include a range of wavelengths that can be recognized as blue.

Optionally, the color adjustment layer CAL may selectively absorb light other than a range of wavelengths between about 500 nm and about 560 nm. In other words, the color adjustment layer CAL may selectively transmit light in a wavelength range between about 500 nm and about 560 nm. That is, the color adjustment layer CAL may selectively absorb light other than a green light wavelength range. However, the range of wavelengths is not limited to the above example, and the range of wavelengths corresponding to the green light may include a range of wavelengths that can be recognized as green.

Optionally, the color adjustment layer CAL may selectively absorb light other than a range of wavelengths between about 560 nm and about 630 nm. In other words, the color adjustment layer CAL may selectively transmit light in a range of wavelengths between about 560 nm and about 630 nm. That is, the color adjustment layer CAL may selectively absorb light other than a yellow light wavelength range. However, the range of wavelengths is not limited to the above example, and the range of wavelengths corresponding to the yellow light may include a range of wavelengths that can be recognized as yellow.

Optionally, the color adjustment layer CAL may selectively absorb light other than a range of wavelengths between about 630 nm and about 680 nm. In other words, the color adjustment layer CAL may selectively transmit light in a range of wavelengths between about 630 nm and about 680 nm. That is, the color adjustment layer CAL may selectively absorb light other than a red light wavelength range. However, the range of wavelengths is not limited to the above example, and the range of wavelengths corresponding to the red light may include a range of wavelength that can be recognized as red.

In an embodiment, the color adjustment layer CAL may include a polymer resin including pigments and/or dyes. That is, the color adjustment layer CAL may have a structure in which pigments and/or dyes may be dispersed in a base resin. Examples of the base resin that can be used as the color adjustment layer CAL may include polyethylene terephthalate (PET), polyimide (PI), polyethersulfone (PS), polyacrylate (PAR), polyetherimide (PEI), polyethylene naphthalate (PEN), polyphenylene sulfide (PPS), polycarbonate (PC), polymethyl methacrylate (PMMA), triacetyl cellulose (TAC), cycloolefin, or epoxy. These materials may be used alone or in combination with each other.

In an embodiment, the color adjustment layer CAL may include a blue pigment and/or a blue dye. The blue pigment may be a commonly used pigment among blue pigments, and the blue dye may be a commonly used dye among blue dyes. For example, the blue pigment may include a blue pigment or a bluish pigment, and the blue dye may include a blue dye or a bluish dye. In this case, the color adjustment layer CAL may selectively absorb light other than a range of wavelengths between about 450 nm and about 500 nm.

Optionally, the color adjustment layer CAL may include a green pigment and/or a green dye. The green pigment may be a commonly used pigment among green pigments, and the green dye may be a commonly used dye among green dyes. For example, the green pigment may include a green pigment or a greenish pigment, and the green dye may include a green dye or a greenish dye. In this case, the color adjustment layer CAL may selectively absorb light other than a range of wavelengths between about 500 nm and about 560 nm.

Optionally, the color adjustment layer CAL may include a yellow pigment and/or a yellow dye. The yellow pigment may be a commonly used pigment among yellowish pigments, and the yellow dye may be a commonly used dye among yellowish dyes. For example, the yellow pigment may include a yellow pigment or a yellowish pigment, and the yellow dye may include a yellow dye or a yellowish dye. In this case, the color adjustment layer CAL may selectively absorb light other than a range of wavelengths between about 560 nm and about 630 nm.

Optionally, the color adjustment layer CAL may include a red pigment and/or a red dye. The red pigment may be a commonly used pigment among red pigments, and the red dye may be a commonly used dye among red dyes. For example, the red pigment may include a red pigment or a reddish pigment, and the red dye may include a red dye or a reddish dye. In this case, the color adjustment layer CAL may selectively absorb light other than a range of wavelengths between about 630 nm and about 680 nm.

In an embodiment, the color adjustment layer CAL may have a thickness of about 10 um or less. Specifically, the thickness of the color adjustment layer CAL may be about 1 um to about 10 um, and preferably about 1 um to about 5 um.

Meanwhile, in FIG. 2, the color adjustment layer CAL may have a single-layer structure and include dyes and/or pigments, but embodiments of the present invention are not limited thereto. That is, the color adjustment layer CAL may selectively absorb light in a specific wavelength range, and a structure and composition of the color adjustment layer CAL are not particularly limited to embodiments described herein. For example, the color adjustment layer CAL may have a multi-layer structure and may not include dyes and/or pigments. That is, the color adjustment layer CAL may have a multi-layer thin film structure capable of selectively absorbing light of a specific wavelength range. In addition, the color adjustment layer CAL may have a structure which may be modified to selectively absorb light of a specific wavelength range by external factors. These factors may include ultraviolet (UV) curing, stress, attraction, etc.

The protective film PF may be disposed on the color adjustment layer CAL and may protect the window WIN. In an embodiment, the protective film PF may include a polymer resin. For example, the protective film PF may include polyethylene terephthalate (PET), polyimide (PI), polyethersulfone (PS), polyacrylate (PAR), polyetherimide (PEI), polyethylene naphthalate (PEN), polyphenylene sulfide (PPS), polycarbonate (PC), polymethyl methacrylate (PMMA), triacetyl cellulose (TAC), cycloolefin, epoxy, or the like.

Meanwhile, although not shown, in another embodiment, a stacking order of the color adjustment layer CAL and the protective film PF may be reversed. That is, the protective film PF may be disposed on the fourth adhesive layer ADL4 and the color adjustment layer CAL may be disposed on the protective film PF. In other words, the protective film PF and the color adjustment layer CAL may be disposed adjacent to each other.

The hard coating layer HC may be disposed on the protective film PF and may have relatively high rigidity. For example, a water contact angle of the hard coating layer HC may be greater than about 90 degrees. In an embodiment, the hard coating layer HC may include a curable resin. Examples of curable resins that can be used as the hard coating layer HC may include acrylate-based compounds, siloxane compounds, or silsesquioxane compounds. These materials may be used alone or in combination with each other.

The first refractive layer RL1 may be disposed on the hard coating layer HC. The first refractive layer RL1 may have a first refractive index. In an embodiment, the first refractive index may be about 1.6 to about 1.8. For example, the first refractive index may be about 1.6 or about 1.7 for light having a wavelength of about 550 nm.

In an embodiment, the first refractive layer RL1 may be formed of an inorganic material. Examples of inorganic materials that can be used as the first refractive layer RL1 may include silicon oxide (SiOx), silicon nitride (SiNx), silicon oxynitride (SiON), aluminum oxide (Al2O3), titanium oxide (TiOx), tantalum oxide (Ta2O5), hafnium oxide (HfOx), zinc oxide (ZnOx), or the like. These materials may be used alone or in combination with each other.

The second refractive layer RL2 may be disposed on the first refractive layer RL1. The second refractive layer RL2 may have a second refractive index. In an embodiment, the second refractive index may be greater than the first refractive index. The second refractive index may be about 1.7 to about 2.0. For example, the second refractive index may be about 1.86 or about 1.968 for light having a wavelength of about 550 nm.

In an embodiment, the second refractive layer RL2 may be formed of an inorganic material. Examples of inorganic materials that can be used as the second refractive layer RL2 may include silicon oxide (SiOx), silicon nitride (SiNx), silicon oxynitride (SiON), aluminum oxide (Al2O3), titanium oxide (TiOx), tantalum oxide (Ta2O5), hafnium oxide (HfOx), zinc oxide (ZnOx), or the like. These materials may be used alone or in combination with each other.

In an embodiment, the second refractive layer RL2 may be subjected to anti-fingerprinting. For example, the second refractive layer RL2 may include an anti-fingerprint material. Examples of anti-fingerprint materials that can be used as the second refractive layer RL2 may include metal oxides (e.g., titanium oxide (TiOx)), silicon-based compounds, fluorine-based compounds, or the like.

The hard coating layer HC, the first refractive layer RL1, and the second refractive layer RL2 may constitute the functional layer FL. As the window protection layer WPL includes the functional layer FL, durability such as abrasion resistance and scratch resistance of the window protection layer WPL may be improved. In addition, a reflectance of the display device DD may be improved so that image quality may be improved.

In an embodiment, the functional layer FL may have a thickness of about 10 um or less. Specifically, the thickness of the functional layer FL may be about 1 um to about 10 um, preferably about 1 urn to about 5 urn.

The display device DD according to an embodiment may include the window protection layer WPL which may protect the window WIN. The window protection layer WPL may include the protective film PF and a color adjustment layer CAL. The color adjustment layer CAL may be disposed below the protective film PF. The color adjustment layer CAL may selectively absorb light in a specific wavelength range. Accordingly, the window protection layer WPL may adjust a reflective color of the display device DD.

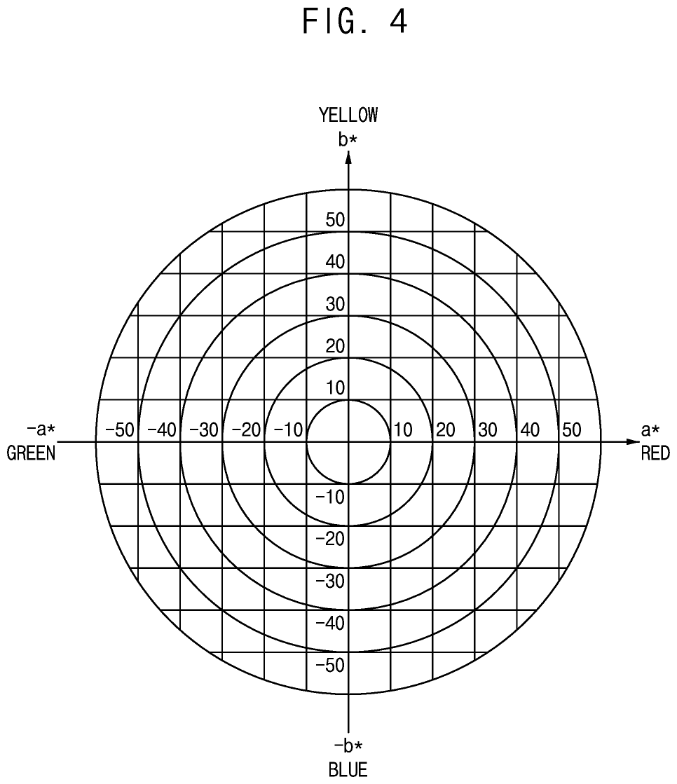

FIG. 4 is a diagram illustrating a CIE-Lab color coordinate system. The CIE-Lab color coordinate system may define a color space in which values of any color may be computed. The CIE-Lab color coordinate system may include a red-green coordinate axis and a yellow-blue coordinate axis. The color space of CIE-Lab color coordinate system may be divided into quadrants including yellow-green hues, green-blue hues, blue-red hues, and red-yellow hues. On the red-green coordinate axis, the a* value indicates a red to green shift, where a positive a* is redder and a negative a* is greener. On the yellow-blue coordinate axis, the b* value indicates a yellow to blue shift, where a positive b* is yellower and a negative b* is bluer. Accordingly, the CIE-Lab color coordinate system may be used to determine a numerical value for color saturation and hue of a color.

Hereinafter, with reference to FIG. 4, a principle of adjusting the reflective color of the display device DD through the window protection layer WPL will be described in more detail.

The reflective color may be expressed using the CIE-Lab color coordinate system. The CIE-Lab color coordinate system uses a* value as a horizontal axis and b* value as a vertical axis, and positive a* value indicates red, negative a* value indicates green, positive b* value indicates yellow, and negative b* value indicates blue. The higher the absolute value of a* and b*, the darker the color. That is, the higher the absolute value of a* and b*, the higher the saturation of the color.

In an embodiment, as a* value and/or b* value of the window protection layer WPL in the CIE-Lab color coordinate system are set in correspondence to a* value and/or b* value of the display panel PNL in the CIE-Lab color coordinate system, a* value and/or b* value of the display device DD may be adjusted.

That is, the reflective color of the display device DD may be adjusted by adjusting a* value and/or b* value of the window protection layer WPL in the CIE-Lab color coordinate system without changing a structure and/or configuration of the display panel PNL.

In an embodiment, the display device DD may satisfy at least one of Equation 1 or Equation 2.

A1×A2<0 [Equation 1]

B1×B2<0 [Equation 2]

In Equation 1, A1 may be a* value of the display panel PNL in a CIE-Lab color coordinate system, and A2 may be a* value of the window protection layer WPL in the CIE-Lab color coordinate system. In Equation 2, B1 may be b* value of the display panel PNL in the CIE-Lab color coordinate system, and B2 may be b* value of the window protection layer WPL in the CIE-Lab color coordinate system.

That is, in an embodiment, the display device DD may have a structure in which a product of a* value (A1) of the display panel PNL and a* value (A2) of the window protection layer WPL in the CIE-Lab color coordinate system is negative and/or a structure in which a product of b* value (B1) of the display panel PNL and b* value (B1) of the window protection layer WPL in the CIE-Lab color coordinate system is negative. That is, at least one of the display panel or the window protection layer selectively absorbs light in a yellow-green hue, a green-blue hue, or a blue-red hue.

For example, when a* value (A1) of the display panel PNL on a red-green coordinate axis is negative, a* value (A1) of the window protection layer WPL in the red-green coordinate axis may be set as positive. That is, when a reflective color of the display panel PNL is in an area of green light, the reflective color of the display device DD may be adjusted by setting a reflective color of the window protection layer WPL to be in an area of red light.

Conversely, when a* value (A1) of the display panel PNL on the red-green coordinate axis is positive, a* value (A2) of the window protection layer WPL on the red-green coordinate axis may be set as negative. That is, when the reflective color of the display panel PNL is in an area of red light, the reflective color of the display device DD may be adjusted by setting the reflective color of the window protection layer WPL to be in an area of green light.

In addition, when b* value (B1) of the display panel PNL on a yellow-blue coordinate axis is negative, b* value (B2) of the window protection layer WPL on the yellow-blue coordinate axis may be set as positive. That is, when the reflective color of the display panel PNL is in an area of blue light, the reflective color of the display device DD may be adjusted by setting the reflected color of the window protection layer WPL to be in an area of yellow light.

Conversely, when b* value (B1) of the display panel PNL on the yellow-blue coordinate axis is positive, b* value (B2) of the window protection layer WPL on the yellow-blue coordinate axis may be set as negative. That is, when the reflective color of the display panel PNL is in an area of yellow light, the reflective color of the display device DD may be adjusted by setting the reflective color of the window protection layer WPL to be in an area of blue light.

In an embodiment, the display device DD may satisfy at least one of Equation 3 or Equation 4.

|A1|>|A3| [Equation 3]

|B1|>|B3| [Equation 4]

In Equation 3, A1 may be a* value of the display panel in a CIE-Lab color coordinate system, and A3 may be a* value of the display device in the CIE-Lab color coordinate system. In Equation 4, B1 may be b* value of the display panel in the CIE-Lab color coordinate system, and B2 may be b* value of the display device in the CIE-Lab color coordinate system.

In an embodiment, the display device DD may have a structure in which an absolute value of a* value (A3) of the display device DD is smaller than an absolute value of a* value (A1) of the display panel PNL on the red-green coordinate axis and a structure in which an absolute value of b* value (B3) of the display device DD is smaller than an absolute value of b* value (B1) of the display panel PNL on the yellow-blue coordinate axis. In an embodiment, the display device DD may have a structure in which an absolute value of a* value (A3) of the display device DD is smaller than an absolute value of a* value (A1) of the display panel PNL on the red-green coordinate axis or a structure in which an absolute value of b* value (B3) of the display device DD is smaller than an absolute value of b* value (B1) of the display panel PNL on the yellow-blue coordinate axis.

That is, a saturation of a color exhibited by the display panel may be greater a saturation of the color displayed by the display device along at least one of the red-green coordinate axis or the yellow-blue coordinate axis. In other words, in the CIE-Lab color coordinate system, when the display panel PNL exhibits a relatively dark reflective color in a specific range of wavelengths, the window protection layer WPL may offset the reflective color. Accordingly, a depth of the color displayed by the display device DD may be lower than a depth of the reflective color exhibited by the display panel PNL.

Accordingly, the reflective color of the display device DD in the CIE-Lab color coordinate system can be adjusted without changing structure and/or configuration of the display panel PNL. Accordingly, the reflective color of the display device DD may be improved, and the image quality of the display device DD may be improved. In addition, a manufacturing process of the display device DD can be simplified, and a manufacturing cost of the display device DD can be reduced.

Table 1 is a comparison table for explaining reflective color measurement results according to comparative examples and embodiments of the present invention.

In Table 1, a* value (A1) and b* value (B1) correspond to the display panel PNL in the CIE-Lab color coordinate system, a* value (A2) and b* value (B2) correspond to the window protection layer WPL in the CIE-Lab color coordinate system, and a* value (A3) and b* value (B3) correspond to the display device DD in the CIE-Lab color coordinate system. The values of Table 1 are the average values measured 5 times using KONICA MINOLTA, CM-3700A equipment. The measurements of a* value (A2) and b* value (B2) correspond to the window protection layer WPL attached on a black tape (3M Company, Electronic Tape). In addition, the corresponding values are given as specular component excluded values.

The display device DD for which the reflective color is measured may include the display panel PNL, the window WIN disposed on the display panel PNL, and the window protection layer WPL disposed on the window WIN.

TABLE 1

| | A1 | B1 | A2 | B2 | A1 × A2 | B1 × B2 | A3 | B3 |
|---|---|---|---|---|---|---|---|---|
| Example 1 | 0.22 | −3.89 | −0.49 | 4.46 | −0.1078 | −17.3494 | 0.15 | −1.96 |
| Example 2 | −1.15 | −5.20 | −0.49 | 4.46 | 0.5635 | −23.192 | −1.33 | −2.86 |
| Example 3 | 0.22 | −3.89 | 0.37 | 5.87 | 0.0814 | −22.8343 | 0.24 | −1.45 |
| Example 4 | −1.15 | −5.20 | 0.37 | 5.87 | −0.4255 | −30.524 | −1.04 | −2.23 |
| Comparative | 0.22 | −3.89 | 0.63 | −1.63 | 0.1386 | 6.3407 | 0.44 | −4.55 |
| Example 1 | | | | | | | | |
| Comparative | −1.15 | −5.20 | −0.50 | −4.09 | 0.575 | 21.268 | −1.18 | −6.05 |
| Example 2 | | | | | | | | |
| Comparative | 0.22 | −3.89 | 3.84 | −1.07 | 0.8448 | 4.1623 | 1.05 | −4.36 |
| Example 3 | | | | | | | | |

In the display device DD according to Examples 1 and 4, both of a product of a* value (A1) of the display panel PNL and a* value (A2) of the window protection layer WPL in the CIE-Lab color coordinate system and a product of the b* value (B1) of the display panel PNL and b* value (B2) of the window protection layer WPL in the CIE-Lab color coordinate system are negative.

In the display device DD according to Examples 2 and 3, a product of b* value (B1) of the display panel PNL and b* value (B2) of the window protection layer WPL in the CIE-Lab color coordinate system is negative.

As illustrated in Examples 1 to 4, the display device DD may have a structure in which the absolute value of a* value (A3) of the display device DD is smaller than the absolute value of a* value (A1) of the display panel PNL in the CIE-Lab color coordinate system and/or a structure in which the absolute value of b* value (B3) of the display device DD is smaller than the absolute value of b* value (B1) of the display panel PNL in the CIE-Lab color coordinate system.

That is, as illustrated in Examples 1 to 4, the window protection layer WPL may perform a function of offsetting the reflective color of the display panel PNL for a specific range of wavelengths corresponding to specific colors in the CIE-Lab color coordinate system, thereby, a depth of the reflective color displayed by the display device DD may be lower than a depth of the reflective color exhibited by the display panel PNL.

On the other hand, in the display device DD according to Comparative Examples 1 to 3, both of a product of a* value (A1) of the display panel PNL and a* value (A2) of the window protection layer WPL in the CIE-Lab color coordinate system and a product of the b* value (B1) of the display panel PNL and b* value (B2) of the window protection layer WPL in the CIE-Lab color coordinate system are positive.

As illustrated in Comparative Examples 1 to 3, the display device DD may have a structure in which the absolute value of a* value (A3) of the display device DD is greater than the absolute value of a* value (A1) of the display panel PNL in the CIE-Lab color coordinate system and/or a structure in which the absolute value of b* value (B3) of the display device DD is greater than the absolute value of b* value (B1) of the display panel PNL in the CIE-Lab color coordinate system.

That is, as illustrated in Comparative Examples 1 to 3, the window protection layer WPL may not offset the reflective color. For example, the window protection layer WPL may not offset the reflective color when the display panel PNL exhibits a relatively dark reflective color of a specific color in the CIE-Lab color coordinate system.

It should be appreciated that the reflective color of the display device DD may be improved, and the image quality of the display device DD may be improved. For example, the display device DD according to embodiments may have a structure in which a product of a* value (A1) of the display panel PNL and a* value (A2) of the window protection layer WPL in the CIE-Lab color coordinate system is negative and a structure in which a product of b* value (B 1) of the display panel PNL and b* value (B 1) of the window protection layer WPL in the CIE-Lab color coordinate system is negative. For example, the display device DD according to embodiments may have a structure in which a product of a* value (A1) of the display panel PNL and a* value (A2) of the window protection layer WPL in the CIE-Lab color coordinate system is negative or a structure in which a product of b* value (B1) of the display panel PNL and b* value (B 1) of the window protection layer WPL in the CIE-Lab color coordinate system is negative.

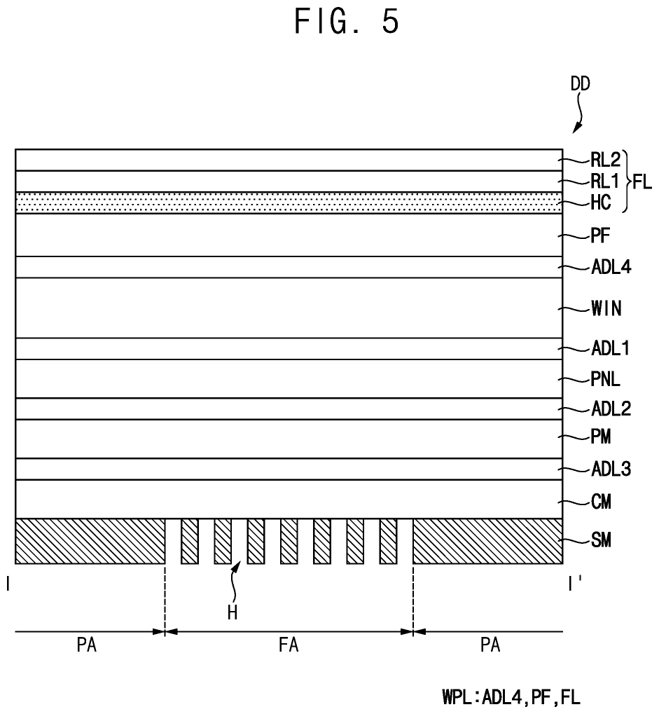

FIGS. 5 to 9 are cross-sectional views illustrating the display device of FIG. 1 according to one or more embodiments. For example, FIGS. 5 to 9 may correspond to the cross-sectional view of FIG. 2.

Hereinafter, differences from the display device DD described with reference to FIGS. 1 to 4 will be described and redundant descriptions thereof may be omitted or simplified.

Referring to FIG. 5, in an embodiment, the hard coating layer HC may selectively absorb light of a specific wavelength range. In this case, a color adjustment layer (e.g., the color adjustment layer CAL of FIG. 2) may be omitted. That is, a* value (A2) and b* value (B2) of the window protection layer WPL in the CIE-Lab color coordinate system may be adjusted through the hard coating layer HC in response to a* value (A1) and the b* value (B1) of the display panel PNL in the CIE-Lab color coordinate system.

In an embodiment, the hard coating layer HC may include a polymer resin including pigments and/or dyes. That is, the hard coating layer HC may have a structure in which pigments and/or dyes may be dispersed in a base resin. In an embodiment, the base resin that can be used as the hard coating layer HC may be a curable resin. Examples of curable resins that can be used as the hard coating layer HC may include acrylate-based compounds, siloxane compounds, or silsesquioxane compounds. These materials may be used alone or in combination with each other.

Meanwhile, descriptions of pigments and/or dyes included in the hard coating layer HC may be substantially the same as descriptions of pigments and/or dyes included in the color adjustment layer CAL described with reference to FIG. 2. Accordingly, a detailed description thereof may be omitted.

Meanwhile, in FIG. 5, the hard coating layer HC may have a single-layer structure and includes dyes and/or pigments, but embodiments of the present invention are not limited thereto. That is, the hard coating layer HC may selectively absorb light in a specific wavelength range, and a structure and configuration of the hard coating layer HC are not particularly limited to embodiments described herein. For example, the hard coating layer HC may have a multi-layer structure and may not include dyes and/or pigments. That is, the hard coating layer HC may have a multi-layer thin film structure capable of selectively absorbing light of a specific wavelength range. In addition, the hard coating layer HC may have a structure which may be modified to selectively absorb light of a specific range of wavelengths by external factors. These factors may include ultraviolet (UV) curing, stress, attraction, etc.

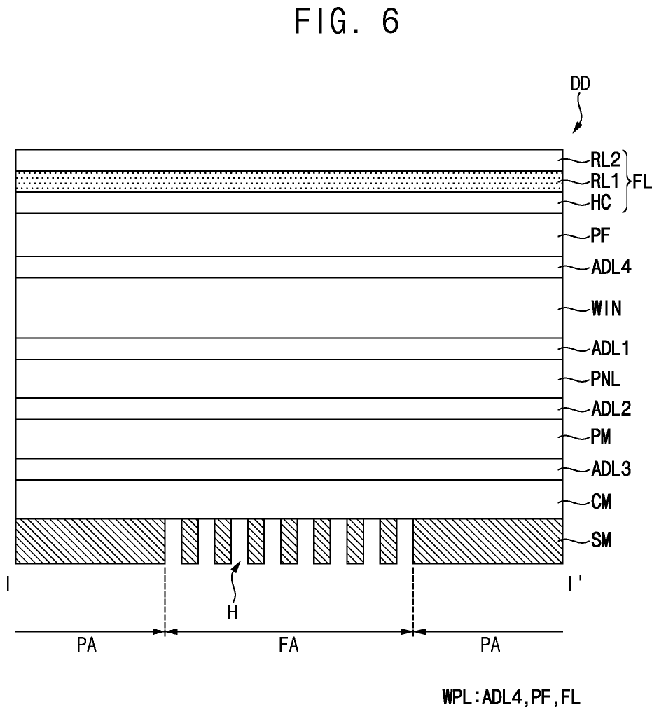

Referring to FIG. 6, in an embodiment, the first refractive layer RL1 may selectively absorb light of a specific wavelength range. In this case, a color adjustment layer (e.g., the color adjustment layer CAL of FIG. 2) may be omitted. For example, as illustrated in FIG. 6, the window protection layer WPL may include the fourth adhesive layer ADL4, the protective film PF, and the functional layer FL. That is, a* value (A2) and b* value (B2) of the window protection layer WPL in the CIE-Lab color coordinate system may be adjusted through the first refractive layer RL1 in response to a* value (A1) and the b* value (B1) of the display panel PNL in the CIE-Lab color coordinate system.

In an embodiment, the first refractive layer RL1 may include a polymer resin including a pigment and/or a dye. That is, the first refractive layer RL1 may have a structure in which pigments and/or dyes may be dispersed in a base resin. In an embodiment, the base resin that can be used as the first refractive layer RL1 may include an inorganic material. Examples of inorganic materials that can be used as the first refractive layer RL1 may include silicon oxide (SiOx), silicon nitride (SiNx), silicon oxynitride (SiON), aluminum oxide (Al2O3), titanium oxide (TiOx), and tantalum oxide. (Ta2O5), hafnium oxide (HfOx), zinc oxide (ZnOx), or the like. These materials may be used alone or in combination with each other.

Meanwhile, descriptions of pigments and/or dyes included in the first refractive layer RL1 may be substantially the same as descriptions of pigments and/or dyes included in the color adjustment layer CAL described with reference to FIG. 2. Accordingly, a detailed description thereof may be omitted.

Meanwhile, in FIG. 6, the first refractive layer RL1 may have a single-layer structure and includes dyes and/or pigments, but embodiments of the present invention are not limited thereto. That is, the first refractive layer RL1 may selectively absorb light in a specific wavelength range, and a structure and configuration of the first refractive layer RL1 are not particularly limited to embodiments described herein. For example, the first refractive layer RL1 may have a multi-layer structure and may not include dyes and/or pigments. That is, the first refractive layer RL1 may have a multi-layer thin film structure capable of selectively absorbing light of a specific wavelength range. In addition, the first refractive layer RL1 may have a structure which may be modified to selectively absorb light of a specific wavelength range by external factors. These factors may include ultraviolet (UV) curing, stress, attraction, etc.

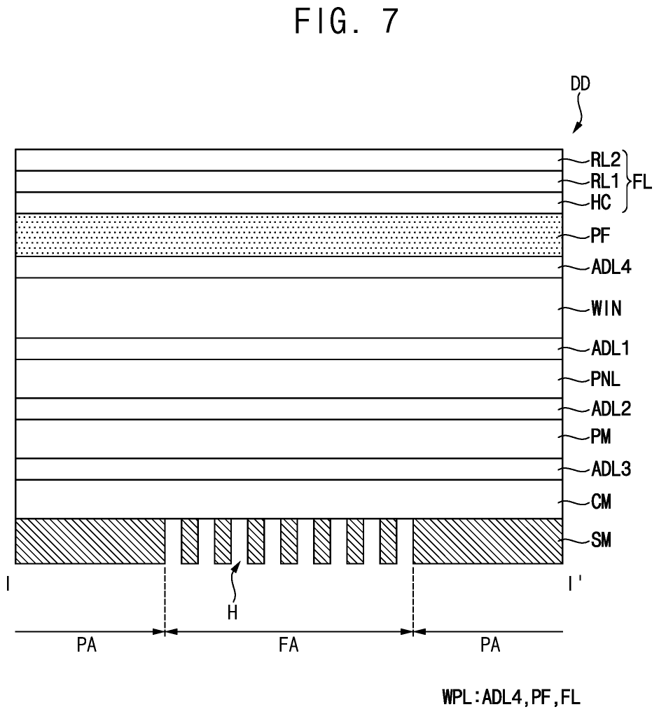

Referring to FIG. 7, in an embodiment, the protective film PF may selectively absorb light of a specific wavelength range. In this case, a color adjustment layer (e.g., the color adjustment layer CAL of FIG. 2) may be omitted. For example, as illustrated in FIG. 7, the window protection layer WPL may include the fourth adhesive layer ADL4, the protective film PF, and the functional layer FL. That is, a* value (A2) and b* value (B2) of the window protection layer WPL in the CIE-Lab color coordinate system may be adjusted through the protective film PF in response to a* value (A1) and the b* value (B1) of the display panel PNL in the CIE-Lab color coordinate system.

In an embodiment, the protective film PF may include a polymer resin including a pigment and/or a dye. That is, the protective film PF may have a structure in which pigments and/or dyes may be dispersed in a base resin. In an embodiment, the base resin that can be used as the protective film PF may include polyethylene terephthalate (PET), polyimide (PI), polyether sulfone (PS), polyacrylate (PAR), polyetherimide (PEI), polyethylene naphthalate (PEN), polyphenylene sulfide (PPS), polycarbonate (PC), polymethyl methacrylate (PMMA), triacetyl cellulose (TAC), cycloolefin, epoxy, or the like. These materials may be used alone or in combination with each other.

Meanwhile, descriptions of pigments and/or dyes included in the protective film PF may be substantially the same as descriptions of pigments and/or dyes included in the color adjustment layer CAL described with reference to FIG. 2. Accordingly, a detailed description thereof may be omitted.

Meanwhile, in FIG. 7, the protective film PF may have a single-layer structure and includes dyes and/or pigments, but embodiments of the present invention are not necessarily limited thereto. That is, the protective film PF may selectively absorb light in a specific wavelength range, and a structure and configuration of the protective film PF are not particularly limited to embodiments described herein. For example, the protective film PF may have a multi-layer structure and may not include dyes and/or pigments. That is, the protective film PF may have a multi-layer thin film structure capable of selectively absorbing light of a specific wavelength range. In addition, the protective film PF may have a structure which may be modified to selectively absorb light of a specific wavelength range by external factors. These factors may include ultraviolet (UV) curing, stress, attraction, etc.

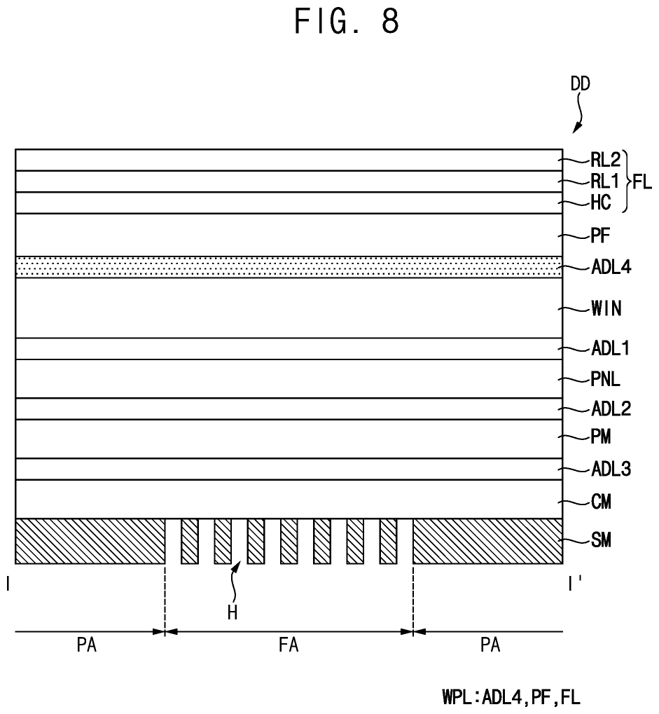

Referring to FIG. 8, in an embodiment, the fourth adhesive layer ADL4 may selectively absorb light of a specific wavelength range. In this case, a color adjustment layer (e.g., color adjustment layer CAL of FIG. 2) may be omitted. For example, as illustrated in FIG. 8, the window protection layer WPL may include the fourth adhesive layer ADL4, the protective film PF, and the functional layer FL. That is, a* value (A2) and b* value (B2) of the window protection layer WPL in the CIE-Lab color coordinate system may be adjusted through the fourth adhesive layer ADL4 in response to a* value (A1) and the b* value (B1) of the display panel PNL in the CIE-Lab color coordinate system.

In an embodiment, the fourth adhesive layer ADL4 may include a polymer resin including a pigment and/or a dye. That is, the fourth adhesive layer ADL4 may have a structure in which pigments and/or dyes may be dispersed in a base resin. In an embodiment, the base resin that can be used as the fourth adhesive layer ADL4 may include an optically transparent adhesive (OCA), an optically transparent adhesive resin (OCR), a pressure-sensitive adhesive (PSA), or the like. These materials may be used alone or in combination with each other.

Meanwhile, descriptions of pigments and/or dyes included in the fourth adhesive layer ADL4 may be substantially the same as descriptions of pigments and/or dyes included in the color adjustment layer CAL described with reference to FIG. 2. Accordingly, a detailed description may be omitted.

Meanwhile, in FIG. 8, the fourth adhesive layer ADL4 may have a single-layer structure and includes dyes and/or pigments, but embodiments of the present invention are not limited thereto. That is, the fourth adhesive layer ADL4 may selectively absorb light in a specific wavelength range, and a structure and configuration of the fourth adhesive layer ADL4 are not particularly limited to embodiments described herein. For example, the fourth adhesive layer ADL4 may have a multi-layer structure and may not include dyes and/or pigments. That is, the fourth adhesive layer ADL4 may have a multi-layer thin film structure capable of selectively absorbing light of a specific wavelength range. In addition, the fourth adhesive layer ADL4 may have a structure which may be modified to selectively absorb light of a specific wavelength range by external factors. These factors may include ultraviolet (UV) curing, stress, attraction, etc.

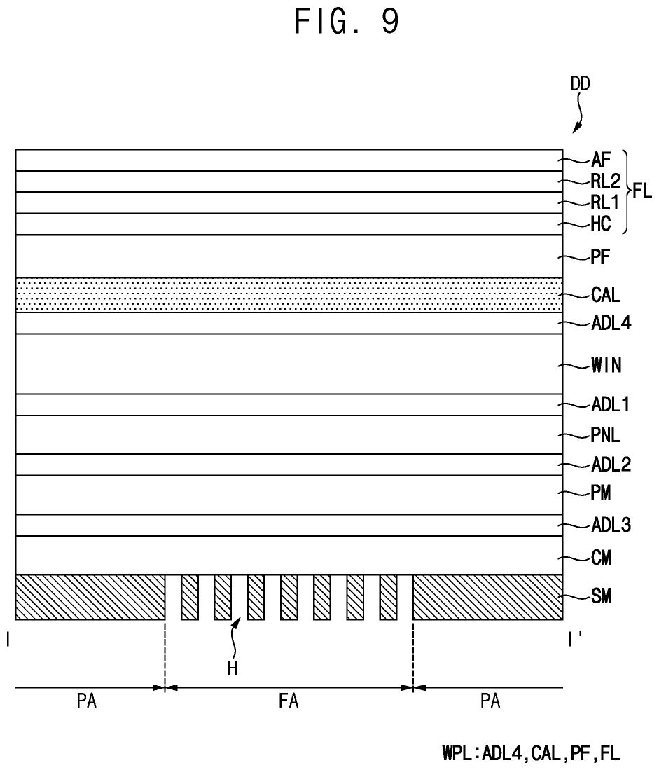

Referring to FIG. 9, in an embodiment, the functional layer FL may further include an anti-fingerprint layer AF including an anti-fingerprint material. In an embodiment, the anti-fingerprint layer AF may be disposed on the second refractive layer RL2. Examples of anti-fingerprint materials that can be used as the anti-fingerprint layer AF may include, for example, metal oxides (e.g., titanium oxide (TiOx)), silicon-based compounds, or fluorine-based compounds.

According to one or more embodiments, the display device DD may include the window protection layer WPL, which may protect the window WIN. As illustrated in FIG. 9, the window protection layer WPL may include the fourth adhesive layer ADL4, the color adjustment layer CAL, the protective film PF, and the functional layer FL. The window protection layer WPL may have a structure in which a plurality of layers including the protective film PF are stacked, and at least one of the plurality of layers of the window protection layer WPL selectively absorbs light of a specific wavelength range. Accordingly, the window protection layer WPL may adjust the reflective color of the display device DD. For example, a* value (A2) and b* value (B2) of the window protection layer WPL in the CIE-Lab color coordinate system may be adjusted through a layer that selectively absorbs light of a specific wavelength range among the plurality of layers of the window protection layer WPL in response to a* value (A1) and the b* value (B1) of the display panel PNL in the CIE-Lab color coordinate system.

Accordingly, the reflective color of the display device DD may be adjusted by adjusting a* value and/or b* value of the window protection layer WPL in the CIE-Lab color coordinate system without changing a structure and/or configuration of the display panel PNL. Accordingly, the reflective color of the display device DD may be improved, and the image quality of the display device DD may be improved. In addition, the manufacturing process of the display device DD can be simplified, and the manufacturing cost of the display device DD can be reduced.

The invention should not be construed as being limited to embodiments set forth herein. Rather, embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel;
a window disposed on the display panel; and
a window protection layer disposed on the window,
wherein at least one of the display panel or the window protection layer selectively absorbs light in a yellow-green hue, a green-blue hue, or a blue-red hue.

2. The display device of claim 1, further comprising:
a folding area of the display panel, the window, and the window protection layer; and
a flat area adjacent to the folding area.

3. The display device of claim 1, wherein the at least one of the display panel or the window protection layer that selectively absorbs light in the yellow-green hue, the green-blue hue, or the blue-red hue, transmits light having a different wavelength than the absorbed light.

4. The display device of claim 1, wherein the display device satisfies at least one of Equation 1 or Equation 2:
A1×A2<0 [Equation 1]
B1×B2<0 [Equation 2]
wherein A1 is a* value of the display panel on a red-green coordinate axis, A2 is a* value of the window protection layer on the red-green coordinate axis, B1 is b* value of the display panel on a yellow-blue coordinate axis, and B2 is b* value of the window protection layer on the yellow-blue coordinate axis.

5. The display device of claim 1, wherein the window protection layer includes:
a protective film disposed on the window; and
an adhesive layer disposed between the window and the protective film.

6. The display device of claim 5, wherein the window protection layer further includes a color adjustment layer disposed below the protective film,
wherein the color adjustment layer selectively absorbs light in a specific wavelength range.

7. The display device of claim 6, wherein the color adjustment layer has a thickness of about 10 um or less.

8. The display device of claim 6, wherein the protective film selectively absorbs light in a first specific wavelength range and the adhesive layer selectively absorbs light of a second specific wavelength range, wherein the first specific wavelength range and the second specific wavelength range are one of a same range or a different range.

9. The display device of claim 5, wherein the window protection layer further includes:
a functional layer disposed on the protective film and having a thickness of about 10 um or less.

10. The display device of claim 9, wherein the functional layer includes a hard coating layer disposed on the protective film.

11. The display device of claim 10, wherein the hard coating layer selectively absorbs light in a specific wavelength range.

12. The display device of claim 11, wherein the functional layer includes:
a first refractive layer disposed on the protective film; and
a second refractive layer disposed on the first refractive layer, having a refractive index lower than a refractive index of the first refractive layer, and including an anti-fingerprint material.

13. The display device of claim 12, wherein the first refractive layer selectively absorbs light of a specific wavelength range.

14. The display device of claim 9, wherein the functional layer includes:
a first refractive layer disposed on the protective film;
a second refractive layer disposed on the first refractive layer and having a refractive index lower than a refractive index of the first refractive layer; and
an anti-fingerprint layer disposed on the second refractive layer.

15. The display device of claim 1, the display panel comprises:
a substrate;
a light emitting devices disposed on the substrate; and
an anti-reflection layer disposed on the light emitting devices and including a light blocking member.

16. The display device of claim 15, wherein the anti-reflection layer further includes:
a plurality of color filters, wherein the color filters correspond to the light emitting devices; and
an overcoat layer disposed on the anti-reflection layer.

17. A display device comprising:
a display panel;
a window disposed on the display panel; and
a window protection layer disposed on the window,
wherein each of the display panel, the window, and the window protection layer include a folding area and a flat area adjacent to the folding area, and
wherein a saturation of a reflective color exhibited by the display panel is greater than a saturation of a color displayed by the display device.

18. The display device of claim 17, wherein the display device satisfies at least one of Equation 3 or Equation 4:

|A1|>|A3| [Equation 3]

|B1|>|B3| [Equation 4]
wherein A1 is a* value of the display panel on a red-green coordinate axis, A3 is a* value of the display device on the red-green coordinate axis, B1 is b* value of the display panel on a yellow-blue coordinate axis, and B2 is b* value of the display device on the yellow-blue coordinate axis.

19. The display device of claim 18, wherein the display device satisfies at least one of Equation 1 or Equation 2:
A1×A2<0 [Equation 1]
B1×B2<0 [Equation 2]
wherein A1 is a* value of the display panel on a red-green coordinate axis, A2 is a* value of the window protection layer on the red-green coordinate axis B1 is b* value of the display panel on a yellow-blue coordinate axis, and B2 is b* value of the window protection layer on the yellow-blue coordinate axis.

20. A display device without a polarizer comprising:
a display panel;
a window disposed on the display panel; and
a window protection layer disposed on the window,
wherein each of the display panel, the window, and the window protection layer include a folding area and a flat area adjacent to the folding area,
wherein the window protection layer offsets a reflective color of the display panel for a specific range of wavelengths, and
wherein a saturation of a color displayed by the display device is less than a saturation of the reflective color exhibited by the display panel in the specific range of wavelengths.
